(19) United States
(12) Patent Application Publication
(10) Pub. No.: US 2013/0139885 A1
(43) Pub. Date: Jun. 6, 2013

(54) PHOTOELECTRIC CONVERSION DEVICE AND METHOD FOR PRODUCING SAME

(71) Applicant: Sanyo Electric Co., Ltd., Osaka (JP)

(72) Inventors: Kazushi ISHIKI, Osaka (JP); Toshio YAGIURA, Osaka (JP)

(73) Assignee: SANYO ELECTRIC CO., LTD., Osaka (JP)

(21) Appl. No.: 13/752,865

(22) Filed: Jan. 29, 2013

Related U.S. Application Data
(63) Continuation of application No. PCT/JP2011/069296, filed on Aug. 26, 2011.

(30) Foreign Application Priority Data
Aug. 31, 2010 (JP) 2010-194548

(51) Int. Cl. H01L 31/048; H01L 31/05; H01L 31/18

(52) U.S. Cl. CPC H01L 31/0504; H01L 31/18
USPC 136/259

(57) ABSTRACT

This photoelectric conversion device comprises a glass substrate (30), a plurality of photoelectric conversion cells (102) constituted by laminating a transparent electrode layer (32), a photoelectric conversion layer (34), and an underside electrode (36) on the glass substrate (30), and a first current collector electrode (38) that connects the photoelectric conversion cells (102) in parallel and collects electric power output by the photoelectric conversion cells (102). At least a part of the first current collector electrode (38) is welded on the glass substrate (30).

### CROSS-REFERENCE TO RELATED APPLICATION

The present application is a continuation application of International Application No. PCT/JP2011/069296, filed Aug. 26, 2011, the entire contents of which are incorporated herein by reference and priority to which is hereby claimed. The PCT/JP2011/069296 application claimed the benefit of the date of the earlier filed Japanese Patent Application No. 2010-194548 filed Aug. 31, 2010, the entire content of which is incorporated herein by reference, and priority to which is hereby claimed.

### TECHNICAL FIELD

The present invention relates to a photoelectric conversion device and a method for producing the same.

### BACKGROUND ART

As power generation systems using sunlight, photoelectric conversion devices in which semiconductor thin films of such as amorphous and microcrystal are stacked have been used.

FIG. 9 shows a cross-sectional view of the basic structure of a conventional photoelectric conversion device 100. Shown in FIG. 9 is a cross-sectional view of an edge portion of the photoelectric conversion device 100. As shown in FIG. 9, the photoelectric conversion device 100 is configured to include a photoelectric conversion cell 102 in which a transparent electrode layer 12, a photoelectric conversion layer 14, and a back electrode 16 are formed on a glass substrate 10; first power collecting electrodes 18 extending along both edge portions of the photoelectric conversion device 100 for collecting electric power generated by the photoelectric conversion cell 102; second power collecting electrodes 20 being laid from the respective first power collecting electrodes to a terminal box; an insulating coating material 22 preventing direct contact between the second power collecting electrodes 20 and the photoelectric conversion cell 102; a back glass 24 sealing a back side of the photoelectric conversion cell 102, the first power collecting electrodes 18 and the second power collecting electrodes 20; and a filling material 26 (EVA) being filled between the photoelectric conversion cell 102 and the back glass 24.

A structure has been suggested in which in order to improve bonding between the first power collecting electrodes 18 and the photoelectric conversion cell 102, the photoelectric conversion layer 14 and the back electrode 16 under the first power collecting electrodes 18 are removed to expose the transparent electrode layer 12 formed on the glass substrate 10 and connecting the first power collecting electrodes 18 to the exposed transparent electrode layer 12 by ultrasonic soldering, conductive tape, or the like (refer to Patent Document 1, 2, and the others).

### PRIOR ART DOCUMENT

### Patent Documents

Patent Document 1: JP 2006-319215A
Patent Document 2: JP 2001-85711A

### DISCLOSURE OF THE INVENTION

### Objects to be Achieved by the Invention

With the structure shown in FIG. 9, reliability of the photoelectric conversion device 100 may be lowered due to poor bonding between the transparent electrode layer 12 to which the first power collecting electrode 18 is connected and the glass substrate 10.

### Means for Achieving the Objects

One aspect of the present invention provides a photoelectric conversion device comprising a glass substrate; a plurality of photoelectric conversion cells formed by stacking a first electrode layer, a photoelectric conversion layer and a second electrode layer on the glass substrate; and power collecting electrode that connects the photoelectric conversion cells in parallel and collects electric power output from the photoelectric conversion cells, wherein at least part of the power collecting electrode is welded to the glass substrate.

Another aspect of the present invention provides a manufacturing method of a photoelectric conversion device, wherein the method comprises a process of welding power collecting electrode to a glass substrate such that the power collecting electrode connects photoelectric conversion cells in parallel via a contact hole formed in photoelectric conversion cells formed by stacking a first electrode layer, a photoelectric conversion layer, and a second electrode layer on the glass substrate.

### Effects of the Invention

According to the present invention, it is possible to improve adhesiveness of power collecting electrode and improve reliability of a photoelectric conversion device.

### BRIEF DESCRIPTION OF THE DRAWINGS

FIG. 1 is a plan view showing a structure of a photoelectric conversion device according to an embodiment of the present invention.

FIG. 2 is a cross-sectional view showing a structure of a photoelectric conversion device according to an embodiment of the present invention.

FIG. 3 is a cross-sectional view showing a structure of a photoelectric conversion device according to an embodiment of the present invention.

FIG. 4 is a plan view used to describe a connection of first power collecting electrodes.

FIG. 5 is a plan view used to describe another example of a connection of the first power collecting electrodes.

FIG. 6 is a cross-sectional view showing another example of a structure of the photoelectric conversion device according to an embodiment of the present invention.

FIG. 7 is a plan view used to describe another example of a connection of the first power collecting electrode according to an embodiment of the present invention.

FIG. 8 is a cross-sectional view showing another example of a structure of the photoelectric conversion device according to an embodiment of the present invention.

FIG. 9 is a cross-sectional view showing a structure of a conventional photoelectric conversion device.

### BEST MODE FOR CARRYING OUT THE INVENTION

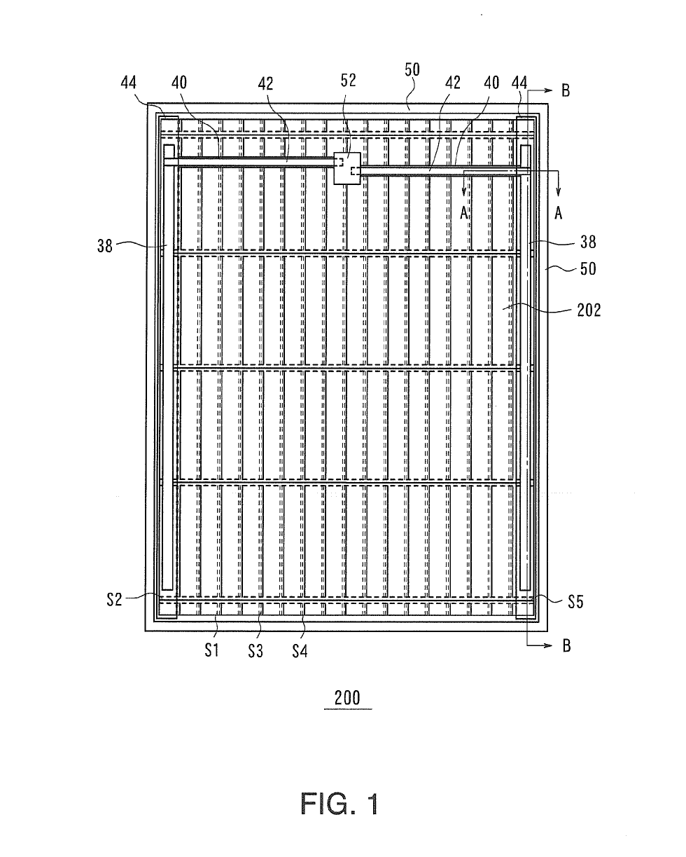

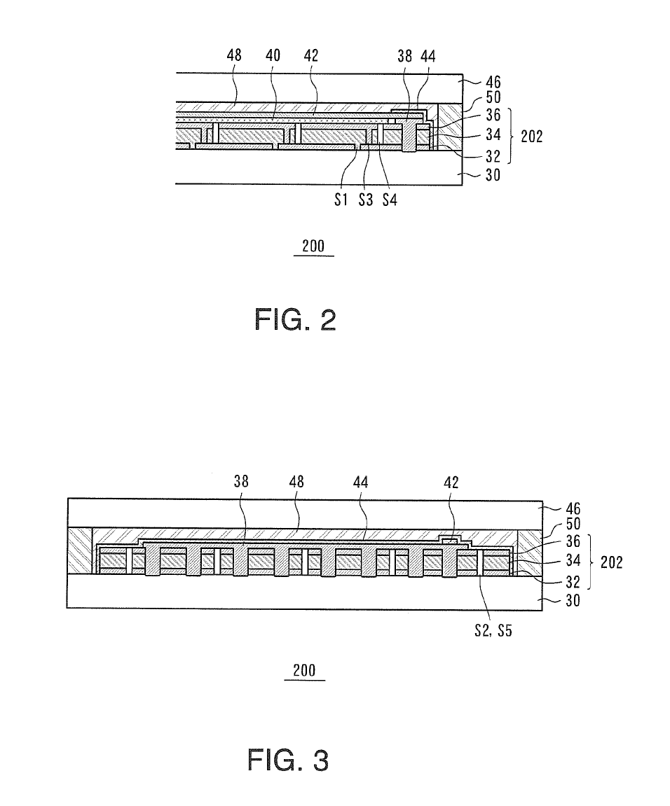

FIGS. 1 to 3 show a structure of a photoelectric conversion device 200 according to an embodiment of the present invention. FIG. 1 is a plan view of the photoelectric conversion device 200 viewed from a back side which is the opposite side to a light receiving surface. FIG. 2 is a cross-sectional view taken along a line A-A in FIG. 1. FIG. 3 is a cross-sectional view taken along a line B-B in FIG. 1. It should be noted that in FIG. 1, in order to clearly show the structure of the photoelectric conversion device 200, overlapped portions which cannot actually be viewed are also illustrated in solid lines. Furthermore, in FIGS. 1 to 3, each portion is not shown according to the actual dimensions for the sake of clear illustration of the structure.

As shown in FIGS. 1 to 3, the photoelectric conversion device 200 is configured to include a glass substrate 30, a transparent electrode layer 32, a photoelectric conversion layer 34, a back electrode 36, a first power collecting electrode 38, a first insulating coating material 40, a second power collecting electrode 42, a second insulating coating material 44, a back surface protective material 46, a filling material 48, an end portion sealing resin 50, and a terminal box 52.

The glass substrate 30 is a member to mechanically support a photoelectric conversion panel of the photoelectric conversion device 200. Formed on the glass substrate 30 is the transparent electrode layer 32. The transparent electrode layer 32 is preferably formed from at least one or a combination of transparent conductive oxide materials (TCO) in which tin (Sn), antimony (Sb), fluorine (F), aluminum (Al) or the like is doped to tin dioxide (SnO₂), zinc oxide (ZnO), indium tin oxide (ITO), or the like. In particular, zinc oxide (ZnO) is preferable because zinc oxide (ZnO) has high translucency, low resistivity, and good plasma resistance. The transparent electrode layer 32 can be formed by a sputtering method or a CVD method.

When applying a structure to connect the photoelectric conversion layers 34 in series, the transparent electrode layer 32 is divided into rectangular patterns. In this embodiment, first slits S1 are formed in and divide the transparent electrode layer 32 along a vertical direction in FIG. 1. On the other hand, when applying a structure to divide the photoelectric conversion layers 34 in parallel, the transparent electrode layer 32 is divided into rectangular patterns in a direction perpendicular to the direction of the first slits S1 forming the above serial connection. In this embodiment, the second slits S2 are formed in and divide the transparent electrode layer 32 in the horizontal direction in FIG. 1. For example, the transparent electrode layer 32 can be patterned by using a YAG laser having a wavelength of 1,064 nm, energy density of 13 J/cm², and pulse frequency of 3 kHz.

Formed on the transparent electrode layer 32 is the photoelectric conversion layer 34 in which a silicon thin film of a p-type layer, i-type layer, and n-type layer are stacked in this order. The photoelectric conversion layer 34 may be a thin film type photoelectric conversion layer such as an amorphous silicon thin film photoelectric conversion layer or a microcrystal silicon thin film photoelectric conversion layer. Furthermore, these photoelectric conversion layers may be stacked as a tandem-type or triple-type photoelectric conversion layer. When the tandem-type or triple-type photoelectric conversion layers are used, it is further possible to apply a structure in which a intermediate layer is sandwiched. The intermediate layer is preferably a transparent conductive oxide material (TCO), for example, a material which is obtained by doping magnesium (Mg) as impurity to zinc oxide (ZnO).

The amorphous silicon thin film photoelectric conversion layer and microcrystal silicon thin film photoelectric conversion layer can be formed by a plasma chemical vapor deposition (CVD) method in which a film is produced by applying plasma processing to mixed gas, in which the following gas may be mixed: silicon containing gas such as silane (SiH₄), disilane (Si₂H₆), dichloro-silane (SiH₂Cl₂); carbon containing gas such as methane (CH₄); p-type dopant containing gas such as diborane (B₂H₆); n-type dopant containing gas such as phosphine (PH₃); and diluent gas such as hydrogen (H₂). As the plasma chemical vapor deposition (CVD) method, it is preferable to apply, for example, a parallel flat plate type RF plasma CVD method of 13.56 MHz.

When two or more cells are connected in series, the photoelectric conversion layer 34 is divided into rectangular patterns. For example, the photoelectric conversion layer 34 may be divided into rectangular patterns by forming a third slit S3 by radiating a YAG laser at a position 50 μm horizontally apart from the first slit dividing the transparent electrode layer 32. It is preferable to use a YAG laser which has, for example, an energy density of 0.7 J/cm² and pulse frequency of 3 kHz.

Formed on the photoelectric conversion layer 34 is the back electrode 36. The back electrode 36 is preferably configured by stacking a transparent conductive oxide material (TCO) and reflective metal in this order. As the transparent conductive oxide material (TCO), the following materials may be used: a transparent conductive oxide material such as tin dioxide (SnO₂) zinc oxide (ZnO), and indium tin oxide (ITO); or a material in which impurity is doped to these transparent conductive oxide materials (TCOs). For example, the transparent conductive oxide material (TCO) may be a material in which aluminum (Al) is doped as impurity to zinc oxide (ZnO). As the reflective metal, silver (Ag), aluminum (Al), or the like may be used. The transparent conductive oxide material (TCO) and the reflective metal can be formed by, for example, a sputtering method or a CVD method. It is preferable to provide concaves and convexes on at least one of the transparent conductive oxide material (TCO) and the reflective metal in order to enhance an optical confinement effect.

When applying a structure to connect two or more photoelectric conversion layers 34 in series, the back electrode 36 is divided into rectangular patterns. The back electrode 36 is divided into rectangular patterns by forming a fourth slit S4 by radiating a YAG laser at a position 50 μm horizontally apart from the third slit dividing the photoelectric conversion layer 34 into patterns. On the other hand, when applying a structure to divide the photoelectric conversion layer 34 in parallel, a fifth slit S5 which divides the photoelectric conversion layer 34 and the back electrode 36 is formed inside the second slit S2 dividing the transparent electrode layer 32. It is preferable to use a YAG laser which has an energy density of 0.7 J/cm² and pulse frequency of 4 kHz.

As described above, the photoelectric conversion cell 202 is formed by stacking the transparent electrode layer 32, the photoelectric conversion layer 34, and the back electrode 36 on the glass substrate 30. Subsequently, the first power collecting electrode 38 and the second power collecting electrode 42 are formed for retrieving electric power generated by the photoelectric conversion cell 202. The first power collecting electrode 38 is used to collect electric power from the photoelectric conversion cell 202 which is divided in parallel, while the second power collecting electrode 42 is used to connect between the first power collecting electrode 38 and the terminal box 52.

First, the first power collecting electrode 38 is provided to extend on the back electrode 36 of the photoelectric conversion cell 202. The first power collecting electrode 38 is formed around an edge of the photoelectric conversion device 200 to connect between positive electrodes or between negative electrodes of the photoelectric conversion layer 34 which is divided in parallel. Therefore, the first power collecting electrode 38 is provided to extend in a direction perpendicular to the parallel dividing direction of the photoelectric conversion layer 34. In other words, as shown in FIGS. 1 and 3, the first power collecting electrode 38 is provided to extend on the back electrode 36 across the second slits S2 and the fifth slits S5 to connect, in parallel, the photoelectric conversion cell 202 which is divided in parallel by the slits S2 and S5. Here, the first power collecting electrode 38 is provided to extend in a vertical direction around the right and left edges in FIG. 1. It should be noted that around the vertical edges shown in FIG. 1, the first power collecting electrode 38 does not extend across the photo conversion layer with no photo conversion function and the second slits S2 and the fifth slits S5 near the vertical edges.

In the above embodiments according to the present invention, as shown in FIGS. 2 and 3, a portion of the back electrode 36, the photoelectric conversion layer 34, and the transparent electrode layer 32 is removed near both edges in the serial connection direction of the photoelectric conversion layer 34 in FIG. 1. The first power collecting electrode 38 is arranged so as to extend over the removal area.

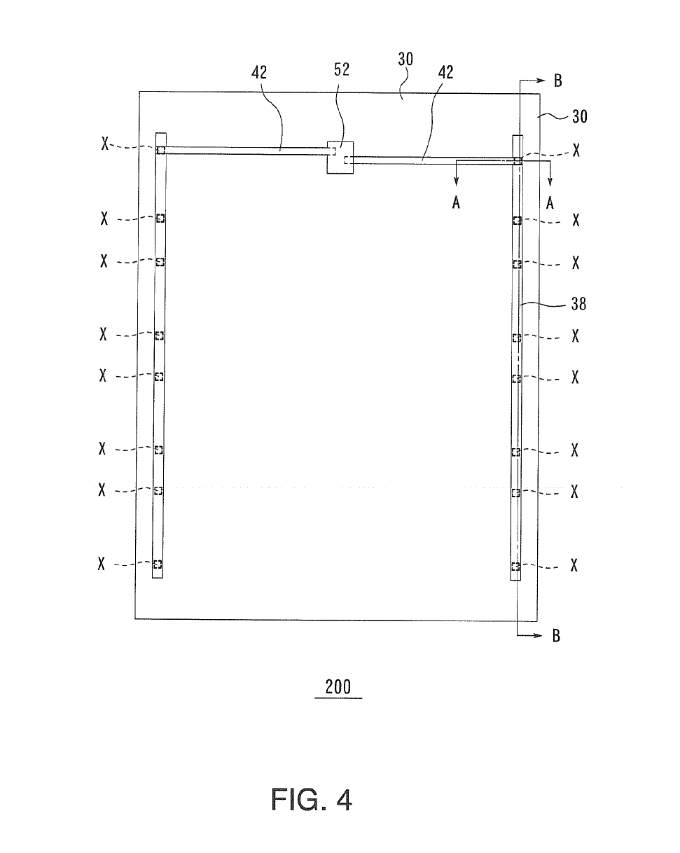

FIG. 4 clearly shows the removal area X (shown in dotted lines) of the back electrode 36, the photoelectric conversion layer 34, and the transparent electrode layer 32 by omitting other elements. As shown in FIG. 4, the removal area X is intermittently formed with space provided therebetween along the lines at both edges in the serial connection direction of the photoelectric conversion layer 34. The removal area X serves as a contact hole through which the first power collecting electrode 38 is welded to the glass substrate 30.

Specifically, the back electrode 36 and the photoelectric conversion layer 34 which are formed in the removal area X are removed by using a YAG laser (wavelength of 532 nm). It is preferable to use a YAG laser with an energy density of 0.7 J/cm² and pulse frequency of 4 kHz. Next, the transparent electrode layer 32 formed in the removal area X is removed by using a YAG laser (wavelength of 1,064 nm). It is preferable to use a YAG laser with an energy density of 13 J/cm² and pulse frequency of 3 kHz.

The first power collecting electrode 38 is provided to extend over the removal areas X formed in the above manner. The first power collecting electrode 38 may be a conductive tape or sheet. Specifically, the first power collecting electrode 38 is preferably a tape or sheet made up of a metal material including 50% or more aluminum. After positioning the first power collecting electrode 38, the first power collecting electrode 38 and the glass substrate 30 are welded in the removal areas X by ultrasonic processing with an energy density of about 0.5 J/mm². In the ultrasonic processing, welding is performed by applying ultrasonic waves while a head of an ultrasonic processor is pressed against the first power collecting electrode 38 over the removal areas X. This ultrasonic processing corresponds to an ultrasonic welding method. In this way, positive electrodes or negative electrodes of the photoelectric conversion cell 202 connected in series are connected in parallel with each other. It should be noted that the first power collecting electrode 38 is preferably positioned to cover the whole of the removal areas X. Further, the first power collecting electrode 38 is preferably made up of 99.999% or more aluminum electrode with a width of 4 to 6 mm and a thickness of 110 μm.

As shown above, by directly welding the glass substrate 30 and the first power collecting electrode 38, it becomes possible to improve reliability of the photoelectric conversion device 200 with an advantage such as a reduced likelihood of delamination of the first power collecting electrode 38.

Next, a first insulating coating material 40 is deposited to form electrical insulation between the second power collecting electrode 42 and the back electrode 36. As shown in FIGS. 1 to 3, the first insulating coating material 40 is provided to extend from near the first power collecting electrode 38, provided along the right and left edges of the photoelectric conversion device 200, to the terminal box 52 located at the center. The first insulating coating material 40 is arranged to extend across the fourth slits S4 over the back electrode 36 in the direction perpendicular to the serial dividing direction. It should be noted that as shown in FIG. 1, the first insulating coating material 40 is provided to extend in a horizontal direction towards the terminal box 52 from near the respective first power collecting electrode 38 on the right and left. The first insulating coating material 40 is preferably formed from an insulating material with resistivity of 10¹⁶ Ωcm or more. Preferable materials are, for example, polyester (PE), polyethylene terephthalate (PET), polyethylene naphthalate (PEN), polyimide, and polyvinyl fluoride. Further, it is preferable to use the first insulating coating material 40 which is coated with an adhesive material in the form of a sticker on the back side. In this way, it becomes possible to reduce the workload for depositing the first insulating coating material 40.

As shown in FIGS. 1 to 3, the second power collecting electrode 42 is provided to extend from the respective first power collecting electrode 38 on the right and left towards the center of the photoelectric conversion device 200 along the first insulating coating material 40. The second power collecting electrode 42 may be made up from the same material as the first power collecting electrode 38, or from copper electrode which has a surface covered by soldering. It is arranged such that the first insulating coating material 40 is sandwiched between the second power collecting electrode 42 and the back electrode 36 in order to prevent direct electrical contact therebetween. One end of the second power collecting electrode 42 is provided to extend over the first power collecting electrode 38 and electrically connected to the first power collecting electrode 38. The second power collecting electrode 42 is preferably electrically connected to the first power collecting electrode 38 by, for example, ultrasonic processing. The other end of the second power collecting electrode 42 is pulled out from an opening of a back glass 50. The other end of the second power collecting electrode 42 is connected to an electrode terminal inside the terminal box 52. In this way, the electric power generated by the photoelectric conversion cell 202 is retrieved outside the photoelectric conversion device 200. As shown in FIGS. 3 and 4, by connecting the first power collecting electrode 38 and the second power collecting electrode 42 in the removal areas X, the second power collecting electrode 42 is directly welded to the first power collecting electrode 38 which is welded to the glass substrate 30. Therefore, the second power collecting electrode 42 becomes less likely to be delaminated, improving reliability the photoelectric conversion device 200. It should be noted that the second power collecting electrode 42 may be electrically connected at a portion other than the first power collecting electrode 38 in the removal areas X.

Next, the second insulating coating material 44 is deposited so as to cover at least portions of the transparent electrode layer 32, the photoelectric conversion layer 34, the back electrode 36, and the first power collecting electrode 38 located near to an end portion sealing resin 50 described below. In particular, it is preferable to place the second insulating coating material 44 so as to cover at least portions of those elements opposing to the end portion sealing resin 50 (end surfaces of the transparent electrode layer 32, the photoelectric conversion layer 34, the back electrode 36, and the first power collecting electrode 38).

In the above embodiments according to the present invention, as shown in FIGS. 2 and 3, the second insulating coating material 44 covers the end portions of the transparent electrode layer 32, the photoelectric conversion layer 34, the back electrode 36, and the first power collecting electrode 38, and is provided to extend in the direction perpendicular to the parallel dividing direction of the photoelectric conversion layer 34 in such a manner that the second insulating coating material 44 does not reach to the end of the first insulating coating material 40.

The second insulating coating material 44 is preferably formed from an insulating material with a resistivity of 10¹⁶ Ωcm or more. Preferable materials are, for example, polyester (PE), polyethylene terephthalate (PET), polyethylene naphthalate (PEN), polyimide, and polyvinyl fluoride. Further, it is preferable to use the second insulating coating material 44 which is coated with adhesive material in the form of sticker on the back side. In this way, it becomes possible to reduce the workload for depositing the second insulating coating material 44.

Next, the end portion sealing resin 50 is deposited. The end portion sealing resin 50 is deposited in the area (7 mm to 15 mm in width) where the photoelectric conversion cell 202 is not formed around an edge portion of the photoelectric conversion device 200. In order to provide an area where the photoelectric conversion cell 202 is not formed around an edge portion of the photoelectric conversion device 200, the edge of the glass substrate 30 may be masked by using a frame material to prevent the formation of the transparent electrode layer 32, the photoelectric conversion layer 34, and the back electrode 36 when forming the photoelectric conversion cell 202 in the film forming process. Alternatively, the photoelectric conversion cell 202 around the edge portion of the photoelectric conversion device 200 may be removed by a laser, sandblasting, or etching after the photoelectric conversion cell 202 is formed. The end portion sealing resin 50 may be deposited by applying it to the area where the photoelectric conversion cell 202 is not formed around an edge portion of the photoelectric conversion device 200 provided in such a manner.

As the end portion sealing resin 50, an insulation material having a resistivity of 10¹⁰ Ωcm or more may be used. Further, the end portion sealing resin 50 is preferably formed from a material with low water permeability in order to prevent ingress of water from an edge portion of the photoelectric conversion device 200. In particular, the end portion sealing resin 50 is preferably formed from a material with permeability with respect to water lower than the filling material 48. The end portion sealing resin 50 is further preferably elastic in order to lessen stress applied to the photoelectric conversion device 200 when mechanical force is applied to the edge portion of the photoelectric conversion device 200. Preferable materials for the end portion sealing resin 50 are, for example, epoxy-based resin and butyl-based resin. More specifically, the use of hot melt butyl is preferable because of easy application and adhesion at high temperature. It should be noted that the end portion sealing resin 50 may be about 6 mm to 10 mm in width and about 0.05 mm to 0.2 mm thicker than the filling material 48.

The back side of the photoelectric conversion device 200 is sealed by using the back surface protective material 46. With the end of the first insulating coating material 40 raised upright, a seal-type filling material 48 is placed over the photoelectric conversion cell 202, the first power collecting electrode 38, the second power collecting electrode 42, or the like. The filling material 48 may be an insulating material. More specifically, the filling material 48 is preferably formed from an insulating material with a resistivity about 10¹⁴ Ωcm. Preferable materials are, for example, ethylene-vinyl acetate copolymer resin (EVA) and polyvinyl butyral (PVB). Further, when the back side of the photoelectric conversion device 200 is covered by the back surface protective material 46, the back surface protective material 46 is positioned while the end portion of the second power collecting electrode 42 is pulled out through the opening portion provided with the back surface protective material 46. The back surface protective material 46 is preferably formed from a material which is electrically insulative, low in water permeability, and high in corrosion resistance. The back surface protective material 46 is preferably, for example, a glass plate.

In such a state, a vacuum laminate process is performed while the back surface protective material 46 is pressed to the photoelectric conversion cell 202 side and heated. The heating process may be performed at, for example, about 150° C. In this way, the back side of the photoelectric conversion device 200 is sealed by the back surface protective material 46. Further, when ethylene-vinyl acetate copolymer resin (EVA) is used as the filling material 48, a curing process may be performed by heating the photoelectric conversion device 200 in a curing furnace. The heating process in the curing process may be performed at, for example, 150° C. for about 30 minutes.

As described above, by sealing the back side of the photoelectric conversion device 200 with the back surface protective material 46, ingress of water or corrosive substances into the photoelectric conversion layer 34 from the back side can be prevented. Accordingly, the environmental resistance of the photoelectric conversion device 200 can be improved.

Lastly, as shown in FIG. 1, a terminal box 52 is installed near the end portion of the second power collecting electrode 42 which is pulled out from the back surface protective material 46 sealing the photoelectric conversion device 200. The terminal box 52 may be installed by adhering it with silicone, or the like. The end portion of the second power collecting electrode 42 is electrically connected to a terminal electrode inside the terminal box 52 by soldering or the like. The terminal box 52 is filled with an insulating resin like silicone before placing a cap thereon. A photoelectric conversion device 200 according to the present embodiment is structured in the above described manner.

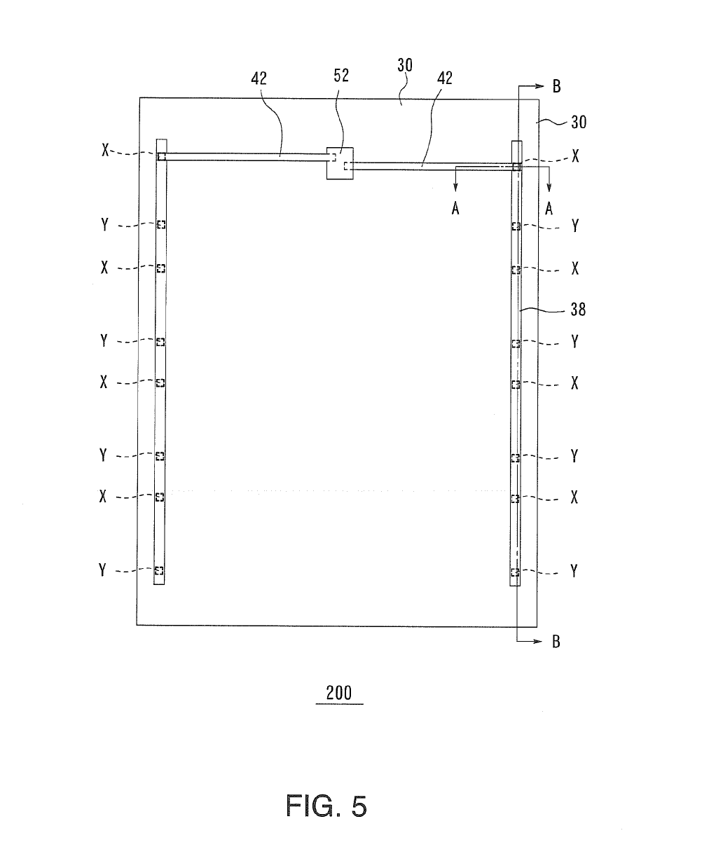

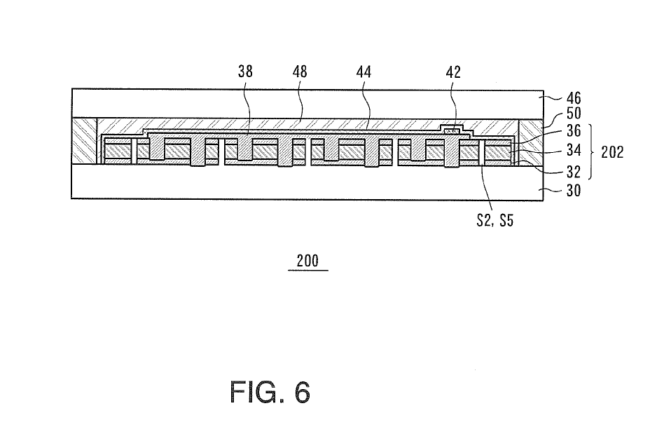

It should be noted that although the first power collecting electrode 38 is described to be welded only to the glass substrate 30 alone in the present embodiment, the first power collecting electrode 38 may be welded to the transparent electrode layer 32 also. In other words, as shown in the plan view in FIG. 5 and cross-sectional view in FIG. 6, a removal area X where the back electrode 36, the photoelectric conversion layer 34, and the transparent electrode layer 32 are removed and a removal area Y where the back electrode 36 and the photoelectric conversion layer 34 are removed but the transparent electrode layer 32 is left may be formed, and an area where the first power collecting electrode 38 and the glass substrate 30 are welded and another area where the first power collecting electrode 38 and the transparent electrode layer 32 are welded may be provided. It should be noted that FIG. 6 shows a cross-sectional view taken along the line B-B in the plan view in FIG. 5. By providing the area where the first power collecting electrode 38 and the transparent electrode layer 32 are welded, it becomes possible to lower the resistance of the electrode when collecting electric power with the first power collecting electrode 38.

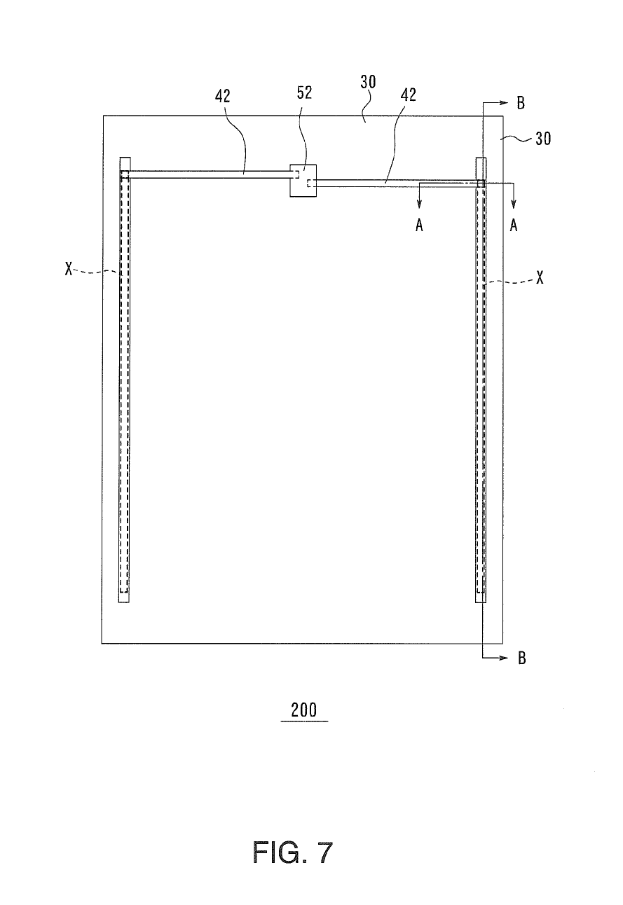

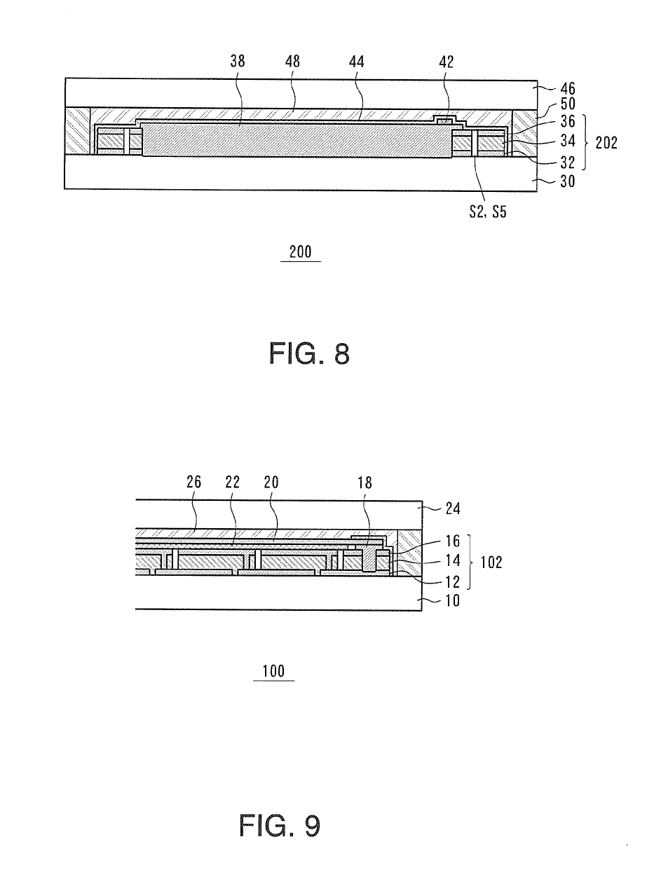

Further, as shown in the plan view in FIG. 7 and the cross-sectional view in FIG. 8, the removal area X where the back electrode 36, the photoelectric conversion layer 34, and the transparent electrode layer 32 are removed may be extended in the form of a line (form of a slit) along both edge portions of the serial connection direction of the photoelectric conversion layer 34 (in other words, the extending direction of the first power collecting electrode 38). Here, the length of the removal area X along both edge portions of the serial connection direction of the photoelectric conversion layer 34 is preferably longer than the width which is perpendicular to the serial connection direction of the photoelectric conversion layer 34. Alternatively, the removal area X is preferably provided to extend in the form of a line (form of a slit) along both edge portions of the photoelectric conversion layer 34 in the serial connection direction of the photoelectric conversion layer 34 so as to cover across at least two of the photoelectric conversion layers 34 along both edge portions of the photoelectric conversion layer 34 in the serial connection direction of the photoelectric conversion layer 34. In this case, it is preferable to form a removal area having a width of about 200 μm in a direction perpendicular to the serial connection direction of the photoelectric conversion layer 34 by radiating laser to the back electrode 36, the photoelectric conversion layer 34, and the transparent electrode layer 32. It should be noted that FIG. 8 shows a cross-sectional view taken along the line B-B in the plan view in FIG. 7.

The removal area Y may be formed by removing the back electrode 36 and the photoelectric conversion layer 34 formed in the removal area X by using a YAG laser (wavelength of 532 nm). Further, in the removal area Y, the first power collecting electrode 38 and the transparent electrode layer 32 may be welded by ultrasonic processing.

Furthermore, the process of forming the removal areas X and Y is not limited to a laser processing and other processes such as sandblasting may be applied.

### REFERENCE NUMERALS

10 glass substrate, 12 transparent electrode layer, 14 photoelectric conversion layer, 16 back electrode, 18 first power collecting electrode, 20 second power collecting electrode, 22 insulating coating material, 24 back glass, 26 filling material, 30 substrate, 32 transparent electrode layer, 34 photoelectric conversion layer, 36 back electrode, 38 first power collecting electrode, 40 first insulating coating material, 42 second power collecting electrode, 44 second insulating coating material, 46 back surface protective material, 48 filling material, 50 end portion sealing resin, 52 terminal box, 100 photoelectric conversion device, 102 photoelectric conversion cell, 200 photoelectric conversion device, 202 photoelectric conversion cell.

1.-8. (canceled)

9. A photoelectric conversion device comprising:
a glass substrate;
a plurality of photoelectric conversion cells formed by stacking a first electrode layer, a photoelectric conversion layer and a second electrode layer on the glass substrate; and
a power collecting electrode that connects the photoelectric conversion cells in parallel and collects electric power output from the photoelectric conversion cells,
wherein at least part of the power collecting electrode is welded to the glass substrate.

10. The photoelectric conversion device according to claim 9,
wherein the power collecting electrode is formed from a metal material including aluminum.

11. The photoelectric conversion device according to claim 9,
wherein the power collecting electrode is welded to the glass substrate via a contact hole formed in the first electrode layer, the photoelectric conversion layer, and the second electrode layer.

12. The photoelectric conversion device according to claim 10,
wherein the power collecting electrode is welded to the glass substrate via a contact hole formed in the first electrode layer, the photoelectric conversion layer, and the second electrode layer.

13. The photoelectric conversion device according to claims 9,
wherein the power collecting electrode is intermittently welded to the glass substrate along a parallel connection direction of the photoelectric conversion cells.

14. The photoelectric conversion device according to claim 10,
wherein the power collecting electrode is intermittently welded to the glass substrate along a parallel connection direction of the photoelectric conversion cells.

15. The photoelectric conversion device according to claim 11,
wherein the power collecting electrode is intermittently welded to the glass substrate along a parallel connection direction of the photoelectric conversion cells.

16. The photoelectric conversion device according to claim 9,
wherein the power collecting electrode is further welded to the second electrode layer.

17. The photoelectric conversion device according to claim 10,
wherein the power collecting electrode is further welded to the second electrode layer.

18. The photoelectric conversion device according to claim 12,
wherein the power collecting electrode is further welded to the second electrode layer.

19. The photoelectric conversion device according to claim 15,
wherein the power collecting electrode is further welded to the second electrode layer.

20. The photoelectric conversion device according to claim 9,
wherein an area in which the power collecting electrode is welded to the glass substrate is provided along both edges along a serial connection direction of the photoelectric conversion cells.

21. The photoelectric conversion device according to claim 10,
wherein an area in which the power collecting electrode is welded to the glass substrate is provided along both edges along a serial connection direction of the photoelectric conversion cells.

22. The photoelectric conversion device according to claim 12,
wherein an area in which the power collecting electrode is welded to the glass substrate is provided along both edges along a serial connection direction of the photoelectric conversion cells.

23. The photoelectric conversion device according to claim 15,
wherein an area in which the power collecting electrode is welded to the glass substrate is provided along both edges along a serial connection direction of the photoelectric conversion cells.

24. The photoelectric conversion device according to claim 19,
wherein an area in which the power collecting electrode is welded to the glass substrate is provided along both edges along a serial connection direction of the photoelectric conversion cells.

25. A manufacturing method of a photoelectric conversion device,
wherein the method comprises a process of welding power collecting electrode to a glass substrate such that the power collecting electrode connects photoelectric conversion cells in parallel via a contact hole formed in the photoelectric conversion cells formed by stacking a first electrode layer, a photoelectric conversion layer, and a second electrode layer on the glass substrate.

26. The manufacturing method of the photoelectric conversion device according to claim 25,
wherein the power collecting electrode is welded to the glass substrate by an ultrasonic welding method.
